(19) United States
(12) Patent Application Publication
(10) Pub. No.: US 2019/0280109 A1
(43) Pub. Date: Sep. 12, 2019

(54) SEMICONDUCTOR DEVICE

(71) Applicant: TOYOTA JIDOSHA KABUSHIKI KAISHA, Toyota-shi (JP)

(72) Inventor: Junichi Saito, Tajimi-shi (JP)

(73) Assignee: TOYOTA JIDOSHA KABUSHIKI KAISHA, Toyota-shi (JP)

(21) Appl. No.: 16/294,368

(22) Filed: Mar. 6, 2019

(30) Foreign Application Priority Data
Mar. 8, 2018 (JP) 2018-042179

(51) Int. Cl. H01L 29/739; H01L 29/861; H01L 27/07; H01L 29/417; H01L 29/08; H01L 29/10

(52) U.S. Cl. CPC H01L 29/7397; H01L 29/8611; H01L 27/0716; H01L 29/083; H01L 29/0804; H01L 29/0821; H01L 29/1095; H01L 29/41708

(57) ABSTRACT

A semiconductor device may include a semiconductor substrate provided with an IGBT range and a diode range. The semiconductor substrate may include n-type emitter regions provided in the IGBT range, a p-type body region provided in the IGBT range, a p-type anode region provided in the diode range and an n-type drift region provided across the IGBT range and the diode range. The drift region in a border inter-trench semiconductor region which is located closest to the diode range may include a high concentration layer. An n-type impurity concentration in the high concentration layer may be higher than the n-type impurity concentration in the drift region under the high concentration layer,

### CROSS-REFERENCE

This application claims priority to Japanese Patent Application No. 201802179 filed on Mar. 8, 2018, the contents of which are hereby incorporated by reference into the present application.

### TECHNICAL FIELD

The technique disclosed herein relates to a semiconductor device.

### BACKGROUND

Japanese Patent Application Publication No. 2012-054403 describes a semiconductor device provided with an IGBT (insulated gate bipolar transistor) and a diode. This semiconductor device has an emitter region of the IGBT, a body region of the IGBT, and an anode region of the diode connected to an upper electrode. Further, a collector region of the IGBT and a cathode region of the diode are connected to a lower electrode. A drift region is provided across an IGBT range and a diode range. The drift region is provided between the body region and the collector region in the IGBT range and is arranged between the anode region and the cathode region in the diode range.

### SUMMARY

In the semiconductor device of Japanese Patent Application Publication No. 2012-054403, the diode is turned on when a potential higher than that of the lower electrode is applied to the upper electrode. That is, current flows from the anode region to the cathode region through the drift region. At this occasion, since the body region is connected to the upper electrode, a forward voltage is applied to a pn junction at an interface between the body region and the drift region. As a result, holes flow from the body region to the cathode region through the drift region. That is, the holes flow in a boundary between the diode range and the IGBT range. When the holes flow in the boundary as above, there is a problem that a forward voltage for turning on the diode is not stabilized. The disclosure herein proposes a technique for suppressing holes flowing in a boundary between a diode range and an IGBT range.

A semiconductor device disclosed herein may comprise an IGBT (insulated gate bipolar transistor) and a diode. This semiconductor device may comprise a semiconductor substrate; an upper electrode covering an upper surface of the semiconductor substrate; and a lower electrode covering a lower surface of the semiconductor substrate. The semiconductor substrate may comprise an IGBT range in which a p-type collector region is provided at a position being in direct contact with the lower electrode; and a diode range in which an n-type cathode region is provided at a position being in direct contact with the lower electrode. A plurality of trenches may be provided in the upper surface of the semiconductor substrate in the IGBT range. Gate insulating films and gate electrodes insulated from the semiconductor substrate by the gate insulating films may be provided in the respective trenches. The semiconductor substrate may further comprise n-type emitter regions provided in the IGBT range, being in direct contact with the upper electrode, and being in direct contact with the gate insulating films; a p-type body region provided in the IGBT range, being in direct contact with the upper electrode, and being in direct contact with the gate insulating films below the emitter regions; a p-type anode region provided in the diode range and being in direct contact with the upper electrode; and an n-type drift region provided across the IGBT range and the diode range, provided below the body region and above the collector region in the IGBT range, provided below the anode region and above the cathode region in the diode range, being in direct contact with the gate insulating films below the body region, and including an n-type impurity concentration lower than an n-type impurity concentration in the cathode region. Each of semiconductor regions located above lower ends of the trenches and interposed between respective pairs of the trenches may be defined as an inter-trench semiconductor region. One of the inter-trench semiconductor regions located at a position closest to the diode range may be defined as a border inter-trench semiconductor region. The drift region in the border inter-trench semiconductor region may comprise a high concentration layer. An n-type impurity concentration in the high concentration layer may be higher than the n-type impurity concentration in the drift region under the high concentration layer.

The high concentration layer may be provided only in the border inter-trench semiconductor region, may be provided in the plurality of inter-trench semiconductor regions including the border inter-trench semiconductor region, or may be provided in all the inter-trench semiconductor regions in the IGBT range.

In this semiconductor device, the drift region in the border inter-trench semiconductor region comprises the high concentration layer having the high n.-type impurity concentration. Due to this, the high concentration layer serves as a barrier to suppress flow of holes. Thus, in this semiconductor device, when the diode is turned on, holes are less likely to flow in a boundary between the diode range and the IGBT range.

### BRIEF DESCRIPTION OF DRAWINGS

FIG. 1 is a cross-sectional view of a semiconductor device of an embodiment.

### DETAILED DESCRIPTION

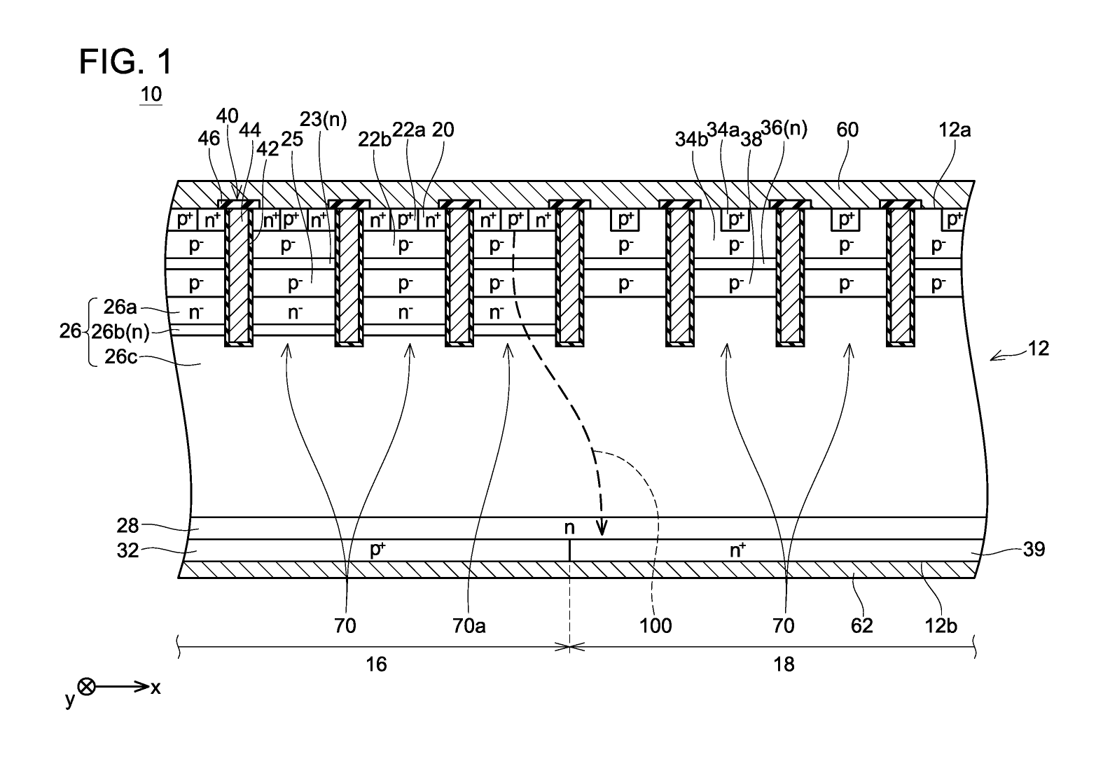

A semiconductor device 10 of an embodiment shown in FIG. 1 includes a semiconductor substrate 12. The semiconductor substrate 12 is constituted of silicon. An upper electrode 60 is provided on an upper surface 12a of the semiconductor substrate 12. A lower electrode 62 is provided on a lower surface 12b of the semiconductor substrate 12.

A p-type collector region 32 and an n-type, cathode region 39 are provided within the semiconductor substrate 12 at positions in direct contact with the lower electrode 62. Hereinbelow, a range that overlaps with the collector region 32 in a plan view of the semiconductor substrate 12 along its thickness direction will be termed an IGBT range 16, and a range that overlaps with the cathode region 39 in the plan view will be termed a diode range 18. Although described later in detail, the IGBT range 16 is provided with an IGBT, and the diode range 18 is provided with a diode. That is, the semiconductor device 10 is a so-called RC-IGBT (reverse-conducting IGBT).

A plurality of trenches 40 is provided in the upper surface 12a of the semiconductor substrate 12. The trenches 40 extend parallel to each other in a direction perpendicular to a sheet surface of FIG. 1 (y direction). The plurality of trenches 40 is arranged along a left-and-right direction of FIG. 1 (x direction) with intervals between them. The plurality of trenches 40 is provided in each of the IGBT range 16 and the diode range 18. Hereinbelow, within the semiconductor substrate 12, each of semiconductor regions located above lower ends of the respective trenches 40 and interposed between respective pairs of trenches 40 will be termed an inter-trench semiconductor region 70. Further, one of the inter-trench semiconductor regions 70 located closest to the diode range 18 within the IGBT range 16 will be termed a border inter-trench semiconductor region 70a.

An inner surface of each trench 40 is covered by a gate insulating film 42. A gate electrode 44 is provided inside each trench 40. The gate electrodes 44 are insulated from the semiconductor substrate 12 by their gate insulating films 42. A front surface of each gate electrode 44 is covered by an interlayer insulating film 46. The gate electrodes 44 are insulated from the upper electrode 60 by their interlayer insulating films 46. A potential of each gate electrode 44 in the IGBT range 16 is controllable from outside. The gate electrodes 44 in the diode range 18 are connected to the upper electrode 60 at positions that are not shown. That is, the gate electrodes 44 in the diode range 18 are dummy electrodes of which potential cannot be controlled.

Each of the inter-trench semiconductor regions 70 in the IGBT range 16 includes emitter regions 20, body contact regions 22a, an upper body region 22b, a barrier region 23, and a lower body region 25.

The emitter regions 20 are n-type regions having a high n-type impurity concentration. The emitter regions 20 are in ohmic contact with the upper electrode 60. The emitter regions 20 are in direct contact with the gate insulating films 42 at upper ends of the trenches 40.

The body contact regions 22a are p-type regions having a high p-type impurity concentration. The body contact regions 22a are in ohmic contact with the upper electrode 60. Each body contact region 22a is adjacent to the emitter regions 20.

The upper body region 22b is a p-type region having a lower p-type impurity concentration than the body contact regions 22a. The upper body region 22b is in direct contact with the emitter regions 20 and the body contact regions 22a from below The upper body region 22b is in direct contact with the gate insulating films 42 below the emitter regions 20.

The barrier region 23 is an n-type region having a lower n-type impurity concentration than the emitter regions 20. The barrier region 23 is in direct contact with the upper body region 22b from below. The barrier region 23 is separated from the emitter regions 20 by the upper body region 22b. The barrier region 23 is in direct contact with the gate insulating films 42 below the upper body region 22b.

The lower body region 25 is a p-type region having a lower p-type impurity concentration than the body contact regions 22a. The lower body region 25 is in direct contact with the barrier region 23 from below. The lower body region 25 is separated from the upper body region 22b by the barrier region 23. The lower body region 25 is in direct contact with the gate insulating films 42 below the barrier region 23.

Each of the inter-trench semiconductor regions 70 in the diode range 18 includes anode contact region 34a, an upper anode region 34b, a barrier region 36, and a lower anode region 38.

The anode contact regions 34a are p-type regions containing p-type impurities at a high concentration. The anode contact regions 34a are in ohmic contact with the upper electrode 60.

The upper anode region 34b is a p-type region having a lower p-type impurity concentration than the anode contact regions 34a. The upper anode region 34b is in direct contact with the anode contact regions 34a from below and from sides. The upper anode region 34b is in direct contact with the gate insulating films 42. A lower end of the upper anode region 34b is located at a substantially same depth as a lower end of the upper body region 22b.

The barrier region 36 is an n-type region and is in direct contact with the upper anode region 34b from below. The barrier region 36 is in direct contact with the gate insulating films 42 below the upper anode region 34b. The barrier region 36 is located at a substantially same depth as the barrier region 23.

The lower anode region 38 is a p-type region having a lower p-type impurity concentration than the anode contact regions 34a. The lower anode region 38 is in direct contact with the barrier region 36 from below. The lower anode region 38 is separated from the upper anode region 34b by the barrier region 36. The lower anode region 38 is in direct contact with the gate insulating films 42 below the barrier region 36. The lower anode region 38 is located at a substantially same depth as the lower body region 25.

A drift region 26 and a buffer region 28 are provided across the IGBT range 16 and the diode range 18.

The drift region 26 is an n-type region having a lower n-type impurity concentration than the cathode region 39. The drift region 26 is in direct contact with the lower body region 25 and the lower anode region 38 from below. The drift region 26 is in direct contact with the gate insulating films 42 below the lower body region 25 and the lower anode region 38. The drift region 26 extends from positions of the lower ends of the lower body region 25 and the lower anode region 38 to a lower side than the lower ends of thee respective trenches 40. The drift region 26 is arranged below the body regions 22a, 22b, 25 and above the collector region 32 in the IGBT range 16. The drift region 26 is arranged below the anode regions 34a, 34b, 38 and above the cathode region 39 in the diode range 18. The drift region 26 includes an upper layer 26a, a floating layer 26b, and a primary layer 26c. An n-type impurity concentration of the floating layer 26b is higher than n-type impurity concentrations of the upper layer 26a and the primary layer 26c. The n-type impurity concentration of the upper layer 26a is substantially equal to the n-type impurity concentration of the primary layer 26c.

The floating layer 26b is provided in each of the inter-trench semiconductor regions 70 including the border inter-trench semiconductor region 70a in the IGBT range 16. In each inter-trench semiconductor region 70, the floating layer 26b extends from one trench 40 to the other trench 40. That is, the floating layer 26b is in direct contact with the gate insulating films 42 located on both sides thereof. The floating layer 26b is provided in the IGBT range 16 but not in the diode range 18.

The upper layer 26a is arranged above the floating layer 26b. The upper layer 26a is in direct contact with the lower body region 25 from below and is in direct contact with the floating layer 26b from above. The upper layer 26a is in direct contact with the gate insulating films 42 located on both sides thereof. The floating layer 26b is separated from the lower body region 25 by the upper layer 26a.

The primary layer 26c is distributed across the IGBT range 16 and the diode range 18. The primary layer 26c is in direct contact with the floating layer 26b from below in the IGBT range 16. Further, the primary layer 26c is in direct contact with the lower anode region 38 from below in the diode range 18. The primary layer 26c is in direct contact with the gate insulating films 42 below the floating layer 26b and below the lower anode region 38. The primary layer 26c is distributed from lower ends of the floating layer 26b and the lower anode region 38 to the lower side than the lower ends of the respective trenches 40.

The buffer region 28 is an n-type region having a higher n-type impurity concentration than the drift region 26. The buffer region 28 is in direct contact with the primary layer 26c of the drift region 26 from below in the IGBT range 16 and in the diode range 18.

The IGBT range 16 is provided with the collector region 32 as aforementioned. The collector region 32 has a high p-type impurity concentration. The collector region 32 is provided in a range including the lower surface 12b, and is in ohmic contact with the lower electrode 62. The collector region 32 is in direct contact with the buffer region 28 from below

The diode range 18 is provided with the cathode region 39 as aforementioned. The cathode region 39 has a higher n-type impurity concentration than the buffer region 28. The cathode region 39 is provided in a range including the lower surface 12b, and is in ohmic contact with the lower electrode 62. The cathode region 39 is in direct contact with the buffer region 28 from below.

The IGBT range 16 is provided with an IGBT connected between the upper electrode 60 and the lower electrode 62, and constituted of the emitter regions 20, the body contact regions 22a, the upper body region 22b, the barrier region 23, the lower body region 25, the drift region 26, the butler region 28, the collector region 32, the gate electrodes 44, and the like. In a case where the semiconductor device 10 operates as the IGBT, the upper electrode 60 is an emitter electrode and the lower electrode 62 is a collector electrode.

The diode range 18 is provided with a diode connected between the upper electrode 60 and the lower electrode 62, and constituted of the anode contact regions 34a, the upper anode region 34b, the barrier region 36, the lower anode region 38, the drift region 26, the buffer region 28, the cathode region 39, and the like. In a case where the semiconductor device 10 operates as the diode, the upper electrode 60 is an anode electrode and the lower electrode 62 is a cathode electrode.

An operation of the IGBT in the IGBT range 16 will be described. When a potential of the gate electrodes 44 is raised to a gate threshold or higher, the upper body region 22b and the lower body region 25 invert to an n-type in vicinities of the gate insulating films 42. Due to this, channels are generated. The channels connect the emitter regions 20, the barrier region 23, and the drift region 26 to each other. Thus, current is enabled to flow from the collector region 32 toward the emitter regions 20. That is, the IGBT is turned on. When the potential of the gate electrodes 44 are reduced to less than the gate threshold, the channels disappear and the IGBT is turned off.

An operation of the diode in the diode range 18 will be described. When a higher potential than that of the lower electrode 62 is applied to the upper electrode 60, a forward voltage is applied to a pn junction at an interface between the lower anode region 38 and the drift region 26. The diode is turned on when this forward voltage exceeds a certain value. As a result, current flows from the anode contact regions 34a toward the cathode region 39 through the upper anode region 34b, the barrier region 36, the lower anode region 38, the drift region 26, and the buffer region 28. The barrier region 36 exists between the upper anode region 34b and the lower anode region 38, however, the current flows from the upper anode region 34b to the lower anode region 38 by passing through the barrier region 36 since the n-type impurity concentration of the barrier region 36 is relatively low. The diode is turned off when the potential of the upper electrode 60 is reduced.

A structure of each inter-trench semiconductor region 70 in the IGBT range 16 (that is, the structure in which the lower body region 25, the barrier region 23, the upper body region 22b, and the body contact region 22a are provided above the drift region 26) is substantially identical to a structure of each inter-trench semiconductor region 70 in the diode range 18 (that is, the structure in which the lower anode region 3$, the barrier region 36, the upper anode region 34b, and the anode contact region 34a are provided above the drift region 26). Due to this, when the diode in the diode range 18 is turned on, a forward voltage is applied to a pn junction at an interface between the lower body region 25 and the drift region 26 in the IGBT range 16. Especially in the border inter-trench semiconductor region 70a close to the cathode region 39, the forward voltage is easily applied to the pn junction at the interface between the lower body region 25 and the drift region 26. Due to this, the pn junction in the border inter-trench semiconductor region 70a is turned on when the diode in the diode range 18 is turned on, and holes flow as shown by an arrow 100 in FIG. 1. That is, the holes flow from the body contact region 22a toward the cathode region 39 through the upper body region 22b, the barrier region 23, the lower body region 25, the drift region 26, and the buffer region 28. When the holes flowing as shown by the arrow 100 are in a large quantity, the forward voltage of the diode thereby varies, and this becomes a factor of variance in a device performance. However, in the semiconductor device 10 of the present embodiment, the floating layer 26b is provided in the border inter-trench semiconductor region 70a. Since the n-type impurity concentration of the floating layer 26b is higher than the n-type impurity concentration of the primary layer 26c, the holes cannot easily flow into the floating layer 26b. Due to this, the floating layer 26b suppresses the flow of the holes shown by the arrow 100. Due to this, there will be less variance in the forward voltage of the diode when the semiconductor device 10 is mass-produced.

Further, as aforementioned, the floating layer 26b is not provided in the diode range 18. Thus, holes flow in the diode range 18 without being affected by the floating layer 26b. Due to this, a loss generated in the diode range 18 can be suppressed.

In the aforementioned embodiment, the floating layer 26b extends from one to the other of the trenches 40 on both sides of each inter-trench semiconductor region 70. However, the floating layer 26b may not be in direct contact with one of or both of the trenches 40 on both sides thereof. Even in such a case, the flow of the holes shown by the arrow 100 can be suppressed to some extent due to the presence of the floating layer 26b in the drift region 26 of the border inter-trench semiconductor region 70a. However, if the floating layer 26b is not in direct contact with the trenches 40, the holes will flow through gaps between the floating layer 26b and the trenches 40, and thus a suppression effect of the flow of the holes becomes lower. Thus, the floating layer 26b preferably extends from one to the other of the trenches 40 on both sides of the border inter-trench semiconductor region 70a.

Further, in the aforementioned embodiment, the upper layer 26a having the low n-type impurity concentration is provided between the floating layer 26b and the lower body region 25, however, the upper layer 26a may not be provided and the floating layer 26b may be in direct contact with the lower body region 25. However, if the floating layer 26b having the relatively high impurity concentration is in direct contact with the lower body region 25, a reverse voltage applied to a pn junction therebetween might exceed a built-in potential, which may possibly turn on the IGBT unintentionally. Thus, it is preferable to provide the upper layer 26a having the low n-type impurity concentration between the floating layer 26b and the lower body region 25.

Further, in the aforementioned embodiment, the upper body region 22b is separated from the lower body region 25 by the barrier region. 23, however, the barrier region 23 may not be provided, and the upper body region 22b and the lower body region 25 may be connected.

Further, in the aforementioned embodiment, the upper anode region 34b is separated from the lower anode region 38 by the barrier region 36, however, the barrier region 36 may not be provided, and the upper anode region 34b and the lower anode region 38 may be connected.

Further, in the aforementioned embodiment, the floating layer 26b is provided in all of the inter-trench semiconductor regions 70 in the IGBT range 16, however, the floating layer 26b may be provided only in the border inter-trench semiconductor region 70a. Further, the floating layer 26b may be provided in only some of the inter-trench semiconductor regions 70 including the border inter-trench semiconductor region 70a.

The floating layer 26b in the aforementioned embodiment is an example of a high concentration layer as claimed.

Some of the technical elements disclosed herein will be listed below. It should be noted that the respective technical elements are independent of one another, and are useful solely or in combinations.

In an example of semiconductor device disclosed herein, the high concentration layer may be in direct contact with each of the gate insulating films that are located on both sides of the border inter-trench semiconductor region.

According to this configuration, the flow of the holes at the boundary of the diode range and the IGBT range can more effectively be suppressed.

In an example of semiconductor device disclosed herein, the drift region may comprise an upper layer provided between the high concentration layer and the body region, and including an n-type impurity concentration lower than the n-type impurity concentration in the high concentration layer.

According to this configuration, the IGBT can be suppressed from unintentionally being turned on.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

What is claimed is:

1. A semiconductor device comprising an IGBT (insulated gate bipolar transistor) and a diode, the semiconductor device comprising:
a semiconductor substrate;
an upper electrode covering an upper surface of the semiconductor substrate; and
a lower electrode covering a lower surface of the semiconductor substrate,
wherein
the semiconductor substrate comprises:
an IGBT range in which a p-type collector region is provided at a position being in direct contact with the lower electrode; and
a diode range in which an n-type cathode region is provided at a position being in direct contact with the lower electrode,
a plurality of trenches is provided in the upper surface of the semiconductor substrate in the IGBT range,
gate insulating films and gate electrodes insulated from the semiconductor substrate by the gate insulating films are provided in the respective trenches,
the semiconductor substrate further comprises:
n-type emitter regions provided in the IGBT range, being in direct contact with the upper electrode, and being in direct contact with the gate insulating films;
a p-type body region provided in the IGBT range, being in direct contact with the upper electrode, and being in direct contact with the gate insulating films below the emitter regions;
a p-type anode region provided in the diode range and being in direct contact with the upper electrode; and
an n-type drift region provided across the IGBT range and the diode range, provided below the body region and above the collector region in the IGBT range, provided below the anode region and above the cathode region in the diode range, being in direct contact with the gate insulating films below the body region, and including an n-type impurity concentration lower than an n-type impurity concentration in the cathode region,
each of semiconductor regions located above lower ends of the trenches and interposed between respective pairs of the trenches is defined as an inter-trench semiconductor region,
one of the inter-trench semiconductor regions located at a position closest to the diode range is defined as a border inter-trench semiconductor region,
the drift region in the border inter-trench semiconductor region comprises a high concentration layer, and
an n-type impurity concentration in the high concentration layer is higher than the n-type impurity concentration in the drift region under the high concentration layer.

2. The semiconductor device of claim I, wherein the high concentration layer is in direct contact with each of the gate insulating films that are located on both sides of the border inter-trench semiconductor region.

3. The semiconductor device of claim 1, wherein the drift region comprises an upper layer provided between the high concentration layer and the body region, and including an n-type impurity concentration lower than the n-type impurity concentration in the high concentration layer.
